(19) United States
(12) Patent Application Publication
(10) Pub. No.: US 2025/0359068 A1
(43) Pub. Date: Nov. 20, 2025

(54) SEMICONDUCTOR DEVICE AND METHOD FOR FABRICATING THE SAME

(71) Applicant: United Microelectronics Corp., Hsin-Chu City (TW)

(72) Inventors: Ching-Hua Hsu, Kaohsiung City (TW); Hui-Lin Wang, Taipei City (TW); Chen-Yi Weng, New Taipei City (TW); Che-Wei Chang, Taichung City (TW); Po-Kai Hsu, Tainan City (TW)

(73) Assignee: United Microelectronics Corp., Hsin-Chu City (TW)

(21) Appl. No.: 18/755,743

(22) Filed: Jun. 27, 2024

(30) Foreign Application Priority Data
May 20, 2024 (TW) 113118594

(51) Int. Cl. H10B 61/00

(52) U.S. Cl. CPC H10B 61/00

(57) ABSTRACT

A semiconductor device includes a substrate, a plurality of memory cells, a dielectric layer and a trench. The substrate defines a memory region having a boundary. The plurality of memory cells are disposed in the memory region. The dielectric layer is disposed on the plurality of memory cells. A top surface of the dielectric layer is higher than a top surface of each of the plurality of memory cells. The trench is disposed in the dielectric layer, and the trench is located between one of the plurality of memory cells closest to the boundary and the boundary. The trench includes an asymmetrical profile.

### BACKGROUND OF THE INVENTION

### 1. Field of the Invention

The present disclosure relates to the field of semiconductor devices, and more particularly, to a semiconductor device including a memory cell and a method for fabricating the same.

### 2. Description of the Prior Art

With the vigorous development of frontier technologies, such as Internet of Things (IoT), edge computing and artificial intelligence, huge information processing capabilities are required, and semiconductor devices including cells as memory such magnetoresistive random-access memory (MRAM) play an indispensable role. However, in part of the manufacturing process of the semiconductor device including the memory cells, the memory cells protrude from the semiconductor device. In the subsequent process of planarizing a dielectric layer covering the memory cells, if the surface of the dielectric layer is accidentally damaged, for example, dents or scratches are formed on the surface of the dielectric layer, it is easy to cause the metal material to fill in the aforementioned dents or scratches during the subsequent metal interconnection process, which may generate bridges between different metal wires and cause short circuits. Accordingly, the performance and/or yield of the semiconductor devices formed later are affected. Therefore, how to improve the semiconductor device including the memory cells and the method for fabricating the same have become the goal of relevant industries.

### SUMMARY OF THE INVENTION

According to one aspect of the present disclosure, a semiconductor device includes a substrate, a plurality of memory cells, a dielectric layer and a trench. The substrate defines a memory region having a boundary. The plurality of memory cells are disposed in the memory region. The dielectric layer is disposed on the plurality of memory cells. A top surface of the dielectric layer is higher than a top surface of each of the plurality of memory cells. The trench is disposed in the dielectric layer, and the trench is located between one of the plurality of memory cells closest to the boundary and the boundary. The trench includes an asymmetrical profile.

According to another aspect of the present disclosure, a method for fabricating a semiconductor device includes steps as follows. A substrate is provided, in which the substrate defines a memory region having a boundary. A plurality of memory cells are formed in the memory region. A dielectric layer is formed to cover the plurality of memory cells, in which the dielectric layer includes a protruding portion located on the plurality of memory cells and a non-protruding portion adjacent to the protruding portion. The protruding portion and a portion of the non-protruding portion are removed to form a trench in the dielectric layer, in which the trench is located between one of the plurality of memory cells closest to the boundary and the boundary, and the trench includes an asymmetrical profile.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7 and FIG. 8 are schematic cross-sectional views showing steps of a method for fabrication a semiconductor device according to an embodiment of the present disclosure.

FIG. 9 is a schematic top view of the semiconductor device in FIG. 8.

FIG. 10 is a schematic cross-sectional view showing a semiconductor device according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

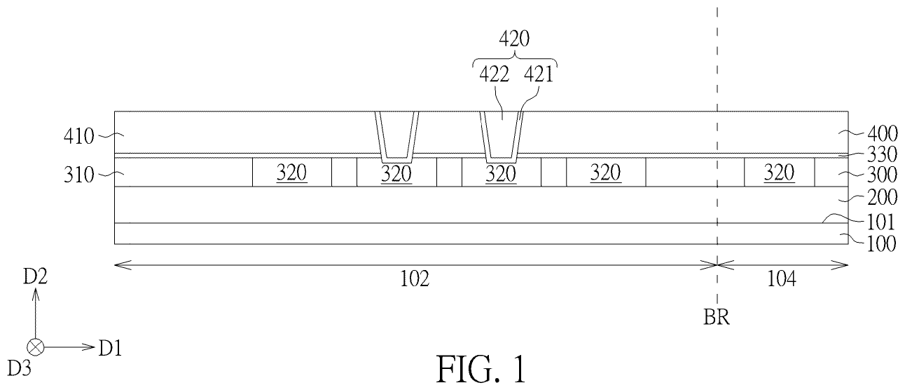

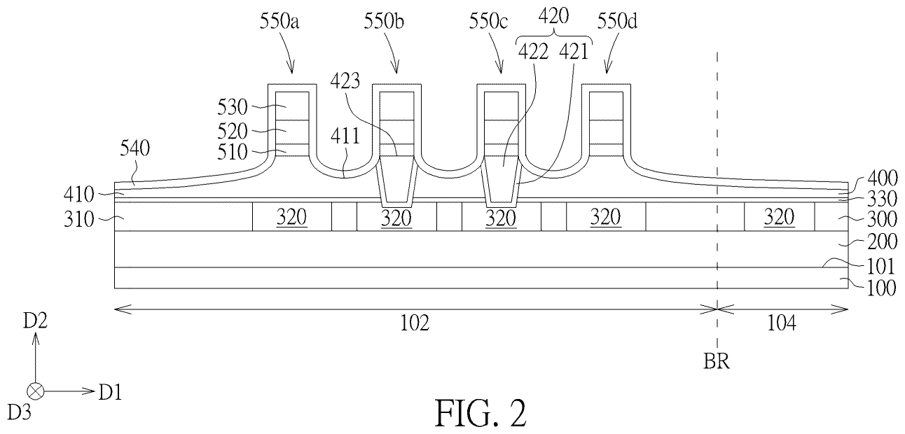

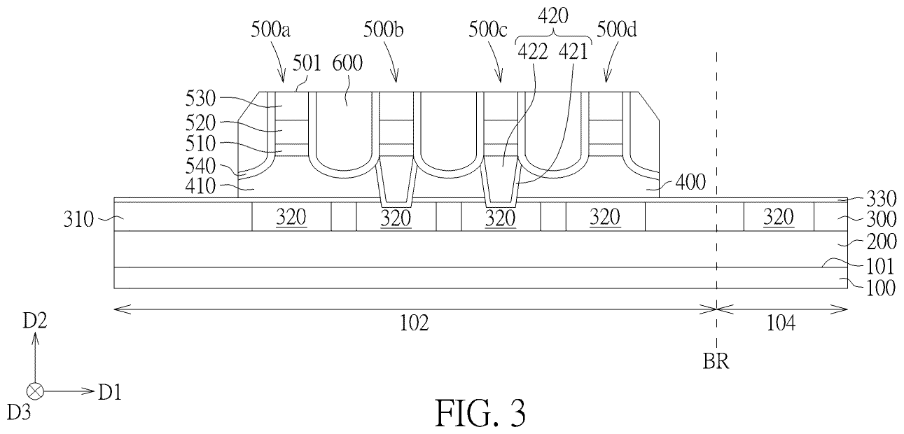

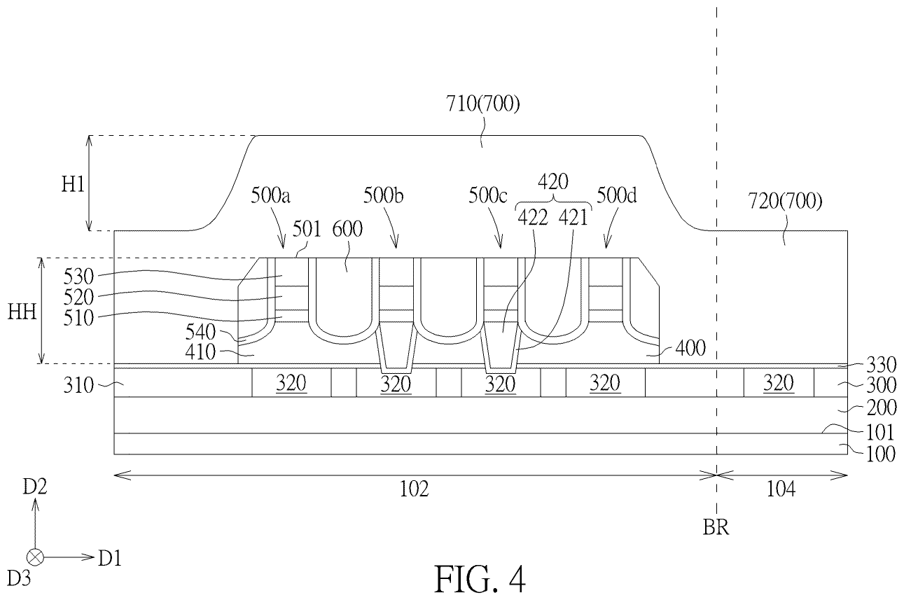

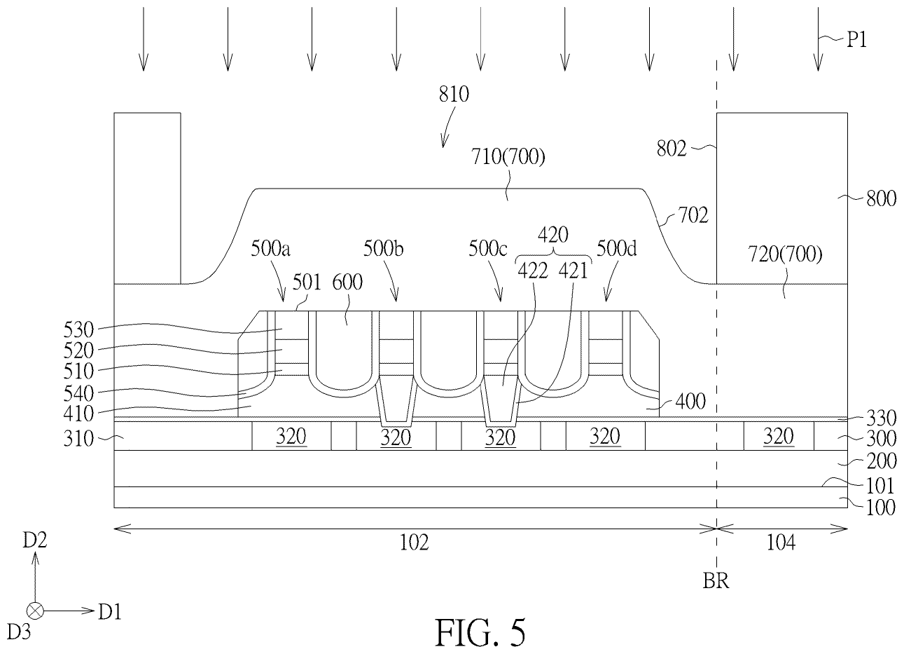

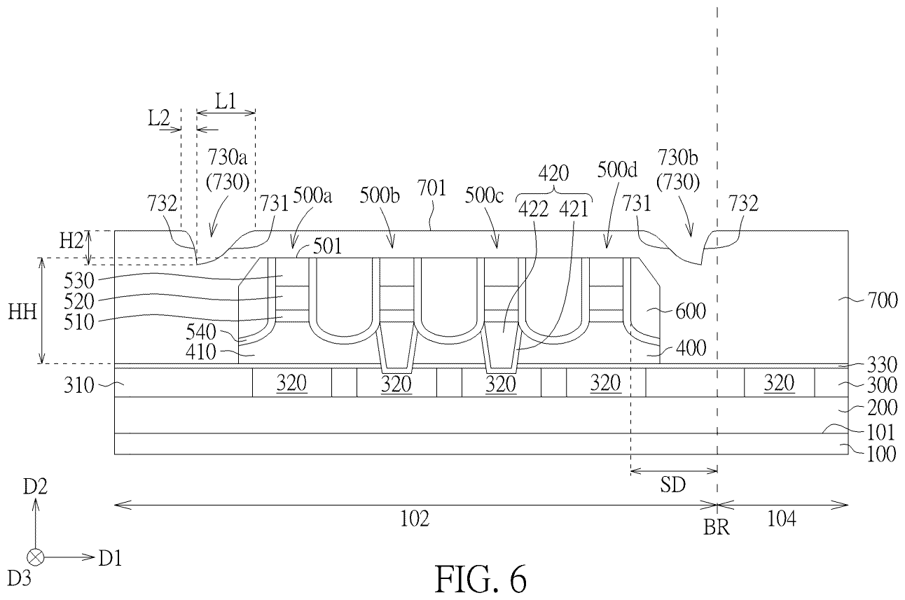

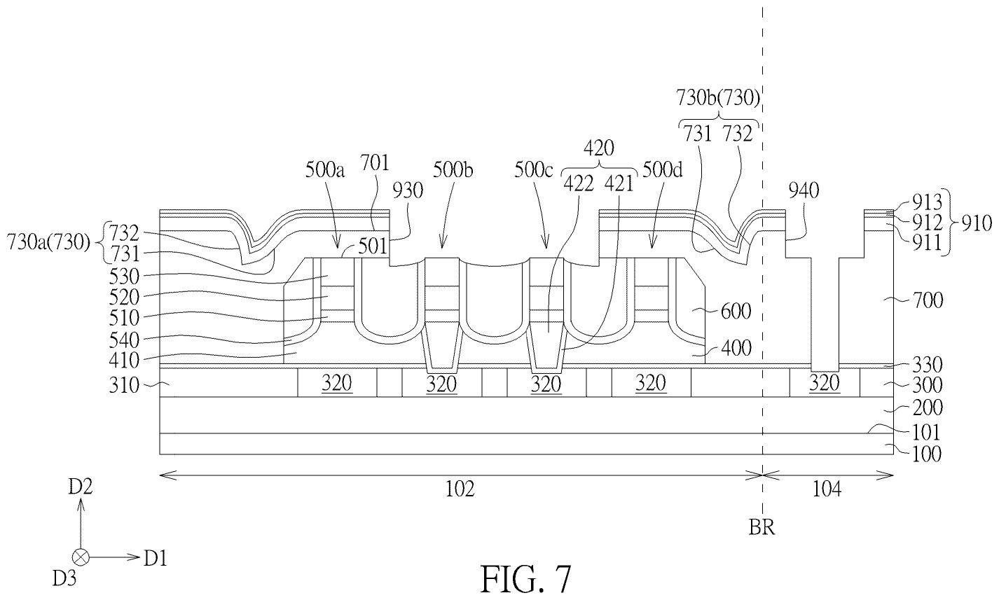

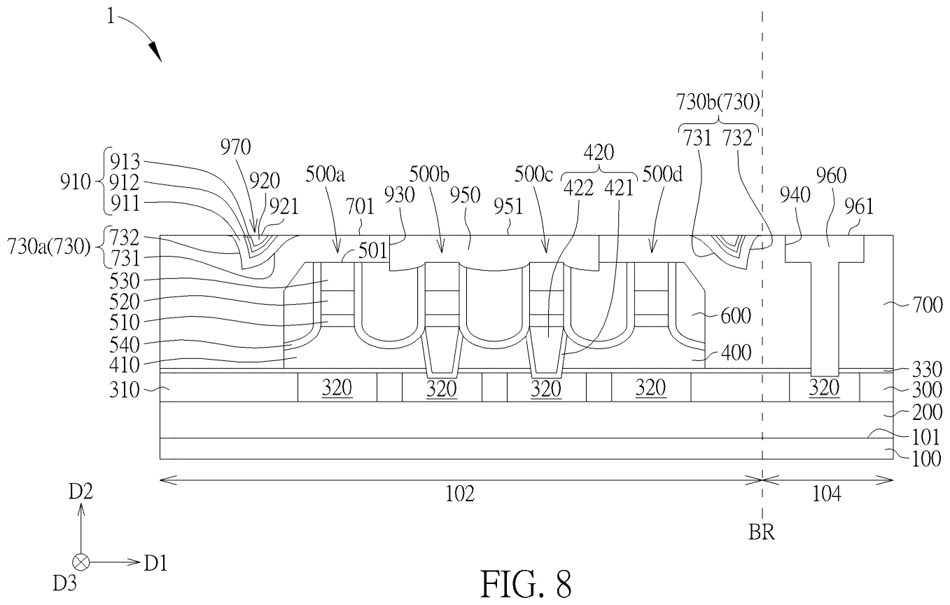

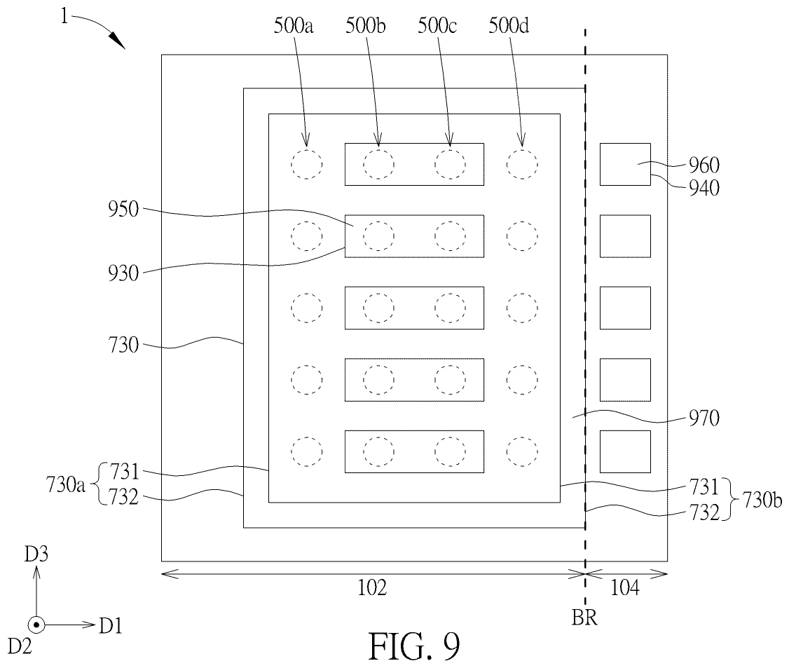

Please refer to FIG. 1 to FIG. 9. FIG. 1 to FIG. 8 are schematic cross-sectional views showing steps of a method for fabrication a semiconductor device according to an embodiment of the present disclosure. FIG. 9 is a schematic top view of the semiconductor device in FIG. 8. In FIG. 1, a substrate 100 is provided. The substrate 100 may be a silicon substrate, an epitaxial silicon substrate, a silicon carbide substrate or a silicon on insulator (SOI) substrate. The substrate 100 may define a memory region 102 and at least one region 104 adjacent to the memory region 102. The memory region 102 has a boundary BR located between the memory region 102 and the region 104. The memory region 102 is configured for disposing a memory cell, such as the memory cells 500a, 500b, 500c and 500d (see FIG. 3) formed later. The memory cell may be, for example, a MRAM cell or a resistive random-access memory (RRAM) cell. The region 104 may be a logic region or a peripheral region, but not limited thereto.

The substrate 100 may include, for example, semiconductor components (not shown) disposed thereon and a dielectric layer 200 covering the aforementioned semiconductor components. The aforementioned semiconductor components may include various active components or passive components, such as a planar or non-planar metal-oxide semiconductor (MOS) transistor, diodes, capacitors, inductors, and resistors, but not limited thereto. In the dielectric layer 200, a plurality of contact plugs (not shown) may be disposed to be electrically connected with the gate (not shown) and/or the source/drain regions (not shown) of the MOS transistor.

Next, a metal interconnect process may be performed to form a metal interconnect structure 300 on the dielectric layer 200 to be electrically connected with the aforementioned contact plugs. The metal interconnect structure 300 includes an inter-metal dielectric layer 310 and wires 320 embedded in the inter-metal dielectric layer 310. The wire 320 may include, for example, a trench conductor, and a material of the wire 320 may include a metal material, such as aluminum (Al), titanium (Ti), tantalum (Ta), tungsten (W), niobium (Nb), molybdenum (Mo), copper (Cu) or a combination thereof, but not limited thereto. According to an embodiment of the present disclosure, the material of the wire 320 includes copper. Herein, the wire 320 is exemplary a single-layer structure. In other embodiment, the wire 320 may be a multi-layer structure. For example, the wire 320 may further include a barrier layer (not shown), and a material of the barrier layer may include titanium (Ti), tantalum (Ta), titanium nitride (TiN), tantalum nitride (TaN) or a combination thereof, but not limited thereto.

Next, a plurality of memory cells 500a, 500b, 500c and 500d (see FIG. 3) are formed in the memory region 102. Herein, the memory cells 500a, 500b, 500c and 500d are exemplary magnetic tunnel junction (MTJ) components. First, a contact etch stop layer (CESL) 330 may be optionally formed on the metal interconnect structure 300. Next, a metal interconnect process may be performed to form a metal interconnect structure 400 on the contact etch stop layer 330. The metal interconnect structure 400 includes an inter-metal dielectric layer 410 and contact structures 420 embedded in the inter-metal dielectric layer 410. The contact structure 420 passes through the contact etch stop layer 330 and is electrically connected with the aforementioned wire 320. The contact structure 420 may include, for example, a via conductor. Herein, the contact structure 420 is exemplary a multi-layer structure and includes a barrier layer 421 and a metal layer 422. A material of the barrier layer 421 may include titanium (Ti), tantalum (Ta), titanium nitride (TiN), tantalum nitride (TaN) or a combination thereof, and a material of the metal layer 422 may include aluminum (Al), titanium (Ti), tantalum (Ta), tungsten (W), niobium (Nb), molybdenum (Mo), copper (Cu) or a combination thereof, but not limited thereto. According to an embodiment of the present disclosure, the material of the barrier layer 421 includes titanium nitride, and the material of the metal layer 422 includes tungsten.

A material of the contact etch stop layer 330 may include a nitride, such as silicon nitride (SiN) or silicon nitricarbide (SiCN), but not limited thereto. A material of each of the inter-metal dielectric layers 310 and 410 may independently include silicon dioxide (SiO₂), tetraethoxysilane (TEOS), silicon nitride (SiN), silicon oxynitride (SiON), silicon nitride carbide (SiCN), nitrogen-doped silicon carbide (NDC), low dielectric constant (low-k) dielectric materials such as fluorinated silica glass (FSG), SiCOH, spin-on glass, ultra-low dielectric constant (ULK) dielectric material, organic polymer dielectric material, plasma-enhanced oxide, or other suitable dielectric materials. The aforementioned ULK dielectric material may include porous dielectric materials, such as silicon oxycarbide (SiOC), but not limited thereto. According to an embodiment of the present disclosure, the inter-metal dielectric layer 310 includes an ULK dielectric material, and the inter-metal dielectric layer 410 includes tetraethoxysilane, but not limited thereto.

Next, as shown in FIG. 2, a MTJ material stack (not shown) may be firstly formed on the metal interconnect structure 400. Forming the MTJ material stack may include sequentially forming a bottom electrode material layer (not shown), a MTJ main structure material layer (not shown) and a top electrode material layer (not shown). Next, semiconductor processes, such as photolithography and etching processes, are performed to remove a portion of the MTJ material stack to form a plurality of MTJ stacks 550a, 550b, 550c and 550d, and then a shielding layer 540 is formed to cover the inter-metal dielectric layer 410 and the top surface and the side surfaces of each of the MTJ stacks 550a, 550b, 550c and 550d. Each of the MTJ stacks 550a, 550b, 550c and 550d may include a bottom electrode layer 510, a MTJ main structure 520 and a top electrode layer 530 from bottom to top. In the process of removing the portion of the MTJ material stack, a portion of the inter-metal dielectric layer 410 is also removed. Therefore, a top surface 411 of the inter-metal dielectric layer 410 is recessed downwardly and is lower than a top surface 423 of each of the contact structures 420.

A material of each of the bottom electrode layer 510 and the top electrode layer 530 may independently include titanium (Ti), tantalum (Ta), titanium nitride (TiN), tantalum nitride (TaN) or a combination thereof. The MTJ main structure 520 may include a pinned layer (not shown), a resistance conversion layer (not shown) and a free layer (not shown) stacked in sequence. Each of the pinned layer and the free layer may independently include a ferromagnetic material, such as iron, cobalt, nickel or an alloy thereof, such as CoFe, NiFe or cobalt-iron-boron (CoFeB), and the material of the resistance conversion layer may include chromium (Cr), ruthenium (Ru), titanium nitride (TiN), tantalum nitride (TaN), aluminum (Al), magnesium (Mg) or magnesium oxide (MgO), but not limited thereto. The material of the shielding layer 540 may include a nitride, such as silicon nitride, but not limited thereto.

Next, as shown in FIG. 3, a dielectric layer 600 is formed to fully cover the shielding layer 540, and then the portions of the dielectric layer 600 and the shielding layer 540 located above the MTJ stacks 550a, 550b, 550c and 550d are removed to expose the top electrode layer 530 of each of the MTJ stacks 550a, 550b, 550c and 550d, so that the memory cells 500a, 500b, 500c and 500d are obtained. Moreover, the portions of the dielectric layer 600 and the shielding layer 540 located at two sides of the memory cells 500a, 500b, 500c and 500d are removed to expose the portion of the contact etch stop layer 330 on which the memory cells 500a, 500b, 500c and 500d are not disposed. A material of the dielectric layer 600 may include a low-k dielectric material, such as a dielectric material with a dielectric constant of 3.5 to 4.5. According to an embodiment of the present disclosure, the material of the dielectric layer 600 includes silicon oxide, and the dielectric layer 600 is formed by an atomic layer deposition (ALD) process. When a gap between any two adjacent ones of the memory cells 500a, 500b, 500c and 500d is small, it is beneficial to fill the dielectric layer 600 into the gap between any two adjacent ones of the memory cells 500a, 500b, 500c and 500d by the atomic layer deposition process.

The memory cell 500b includes the contact structure 420, the MTJ stack 550b and the shielding layer 540 disposed on the side surfaces of the MTJ stack 550b. The memory cell 500c includes the contact structure 420, the MTJ stack 550c and the shielding layer 540 disposed on the side surfaces of the MTJ stack 550c. The memory cell 500a includes the MTJ stack 550a and the shielding layer 540 disposed on the side surfaces of the MTJ stack 550a, and the memory cell 500d includes the MTJ stack 550d and the shielding layer 540 disposed on the side surfaces of the MTJ stack 550d. Because there are no contact structures 420 disposed below the MTJ stacks 550a and 550d, the memory cells 500a and 500d are dummy memory cells. That is, among the memory cells 500a, 500b, 500c and 500d, the memory cell 550d is closest to the boundary BR, and the memory cell 550d is a dummy memory cell.

The memory cells 500a, 500b, 500c and 500d may be arranged along the horizontal directions D1 and D3 to form an array, such as a rectangular array (see FIG. 9), but not limited thereto. In other embodiment, the number and the arrangement of the memory cells may be adjusted according to actual needs, and the shape of the array may be adjusted accordingly. The relevant principles of the memory cells 500a, 500b, 500c and 500d are well known in the art and are not described in detail herein. At this stage, the memory cells 500a, 500b, 500c and 500d protrude from the surface of the semiconductor device (not labeled) shown in FIG. 3. For example, the memory cells 500a, 500b, 500c and 500d protrude relative to the contact etch stop layer 330 in the vertical direction D2. The aforementioned vertical direction D2, for example, may be perpendicular to the top surface 101 of the substrate 100.

Next, as shown in FIG. 4, a dielectric layer 700 is formed to cover the plurality of memory cells 500a, 500b, 500c and 500d. The dielectric layer 700 substantially follows the surface morphology of the memory cells 500a, 500b, 500c and 500d and the dielectric layer 600, and thus includes a protruding portion 710 and a non-protruding portion 720. The protruding portion 710 is disposed adjacent to the non-protruding portion 720. The protruding portion 710 is located on the memory cells 500a, 500b, 500c and 500d, and the non-protruding portion 720 is located on the region of the contact etch stop layer 330 without the memory cells 500a, 500b, 500c and 500d. In the embodiment, the memory cells 500a, 500b, 500c and 500d are arranged to form the rectangular array (see FIG. 9), so that the protruding portion 710 may have a rectangular shape in the top view of the semiconductor device, but not limited thereto. For example, the shape of the protruding portion 710 may correspond to the shape of the array formed by the memory cells 500a, 500b, 500c and 500d. The protruding portion 710 may have a protruding height H1 relative to the non-protruding portion 720. The protruding height H1 may be substantially identical to a height HH of one of the memory cells 500a, 500b, 500c and 500d in the vertical direction D2. For example, the following condition may be satisfied: 1600 Å≤HH≤1750 Å. The aforementioned protruding height H1 may be a height of the protruding portion 710 protruding relative to the non-protruding portion 720 in the vertical direction D2. The aforementioned protruding height HH may be defined as a height difference between the top surface 501 of one of the memory cells 500a, 500b, 500c and 500d and the film layer (herein, the contact etch stop layer 330) below the one of the memory cells 500a, 500b, 500c and 500d in the vertical direction D2.

A material of the dielectric layer 700 may include an ULK dielectric material, such as a dielectric material with a dielectric constant less than 4, and preferably a dielectric material with a dielectric constant of 2 to 3.5. The ULK dielectric material may include porous dielectric materials, such as, but not limited to, silicon oxycarbide (SiOC). In other embodiment, the dielectric layer 600 may be omitted, and the dielectric layer 700 directly fills the gaps between the memory cells 500a, 500b, 500c and 500d and covers the memory cells 500a, 500b, 500c and 500d. In this case, the portion of the shielding layer 540 on the top electrode layer 530 of each of the memory cells 500a, 500b, 500c and 500d is reserved, and may be removed in subsequent process according to actual needs.

Next, as shown in FIG. 5 and FIG. 6, the protruding portion 710 and a portion of the non-protruding portion 720 are removed to form a trench 730 in the dielectric layer 700, and the trench 730 is located between the memory cell 500d and the boundary BR, which may include steps as follows. First, as shown in FIG. 5, a patterned mask 800 is formed on the dielectric layer 700, in which the patterned mask 800 has an opening 810 exposing the protruding portion 710 and a portion of the non-protruding portion 720. That is, the patterned mask 800 surrounds the protruding portion 710 and the portion of the non-protruding portion 720 exposed from the opening 810. As mentioned above, the protruding portion 710 may have a rectangular shape in the top view of the semiconductor device, so that the opening 810 may correspond to the protruding portion 710 to have a rectangular shape in the top view of the semiconductor device, but not limited thereto. The shapes of the protruding portion 710 and the opening 810 may be adjusted according to the arrangement of the memory cells 500a, 500b, 500c and 500d.

Next, an etching process P1 may be performed to etch the protruding portion 710 and the portion of the non-protruding portion 720 exposed from the opening 810. As shown in FIG. 6, the trench 730 is formed in the dielectric layer 700 adjacent to the patterned mask 800. Afterward, the patterned mask 800 is removed. The aforementioned etching process P1 only removes the dielectric layer 700 and does not remove the memory cells 500a, 500b, 500c and 500d and the dielectric layer 600. That is, after the etching process P1, the dielectric layer 700 remains to cover the memory cells 500a, 500b, 500c and 500d and the dielectric layer 600 completely, and the memory cells 500a, 500b, 500c and 500d and the dielectric layer 600 are not exposed from the dielectric layer 700.

In the top view of the semiconductor device, the trench 730 has an annular shape (see FIG. 9) and surrounds the plurality of memory cells 500a, 500b, 500c and 500d. In the embodiment, the trench 730 corresponds to the shapes of the protruding portion 710 and the opening 810 to have a rectangular annular shape, but not limited thereto. The shape of the trench 730 may be changed corresponding to the shapes of the protruding portion 710 and the opening 810. The left portion 730a and the right portion 730b of the trench 730 are respectively located at the outer sides of the outermost two memory cells 500a and 500d of the plurality of memory cells 500a, 500b, 500c and 500d in the horizontal direction D1. Specifically, the left portion 730a of the trench 730 is located at the outer side of the memory cell 500a, and the right portion 730b of the trench 730 is located between the memory cell 500d and the boundary BR. The aforementioned outer side is based on the center point (not shown) of the memory region 102. In the memory region 102, when a component is closer to the outer side than another component, it represents that a distance between the component and the center point of the memory region 102 is greater than a distance between the another component and the center point of the memory region 102.

As shown in FIG. 6, in a cross-sectional view of the semiconductor device, each of the left portion 730a and the right portion 730b of the trench 730 includes a V-shape or a triangle. Specifically, the trench 730 includes a first sidewall 731 and a second sidewall 732 disposed oppositely. The first sidewall 731 is closer to the center point (not shown) of the memory region 102 than the second sidewall 732, and the first sidewall 731 is closer to the memory cell 500d (i.e., the one of the memory cells 500a, 500b, 500c and 500d closest to the boundary BR) than the second sidewall 732. Each of the left portion 730a and the right portion 730b of the trench 730 includes a V-shape, in which the V-shape may refer to the shape together formed by the first sidewall 731 and the second sidewall 732. Each of the left portion 730a and the right portion 730b of the trench 730 includes a triangle, in which the triangle may refer to the shape together formed by the first sidewall 731, the second sidewall 732 and the opening at the top of the trench 730.

The etching process P1 may be a dry etching process. Thereby, it is beneficial for the first sidewall 731 and the second sidewall 732 to inherit the profiles of the protruding portion 710 of the dielectric layer 700 and the patterned mask 800, respectively. As shown in FIG. 5, the patterned mask 800 has a vertical side surface 802, and the protruding portion 710 has an inclined side surface 702. Compared with the vertical side surface 802, the inclined degree of the inclined side surface 702 is gentler and includes a concave curve (herein, concave upwardly). Therefore, the first sidewall 731 and the second sidewall 732 are asymmetrical to each other. That is, the trench 730 includes an asymmetrical profile. In some embodiments, the inclined degree of the first sidewall 731 is smaller than the inclined degree of the second sidewall 732. In some embodiments, the first sidewall 731 may include an concave curve (herein, concave upwardly), and the second sidewall 732 may include a convex curve (herein convex upwardly). The aforementioned inclined degree of the sidewall may refer to a height of the sidewall in the vertical direction D2 divided by a length of the sidewall in the horizontal direction D1. As shown in FIG. 6, the inclined degree of the first sidewall 731 is equal to the height H2 divided by the length L1 (H2/L1), and the inclined degree of the second sidewall 732 is equal to the height H2 divided by the length L2 (H2/L2).

In FIG. 6, one of the plurality of memory cells 500a, 500b, 500c and 500d has a height HH in the vertical direction D2, a distance SD is between a side of the trench 730 adjacent to the boundary BR and the one of the plurality of memory cells 500a, 500b, 500c and 500d closest to the boundary BR in a horizontal direction D1 (herein, the memory cell 500d), and the following condition may be satisfied: 0<SD≤2HH. Thereby, it is beneficial for the trench 730 to have a complete and stable annular shape. For example, the following condition may be satisfied: 120 nm≤SD≤350 nm. Thereby, the distance SD is proper, which is beneficial for the trench 730 to have a stable annular shape, and the trench 730 is not too large to occupy an excessive area. The trench 730 in the aforementioned definition of the distance SD may refer to the right portion 730b of the trench 730 located between the memory cell 500d and the boundary BR. Moreover, the distance SD varies along the vertical direction D2, the aforementioned range of the distance SD may be the range of the distance SD at the top of the trench 730.

Next, a plug process is performed. As shown in FIG. 7, contact vias 930 and 940 are formed in the dielectric layer 700, which may include steps as follows. First, a mask layer 910 is formed to completely cover the dielectric layer 700. Next, semiconductor processes, such as one or more photolithography and etching processes, may be performed to remove portions of the mask layer 910, the dielectric layer 700 and the shielding layer 540 of the memory cells 500b and 500c, so as to form the contact vias 930 and 940 in the memory region 102 and the region 104, respectively. The contact via 930 exposes the memory cells 500b and 500c. For example, the contact via 930 exposes the top surfaces of top electrode layers 530 of the memory cells 500b and 500c, and may optionally expose portions of the side surfaces of top electrode layers 530 of the memory cells 500b and 500c. The contact via 940 exposes the wire 320 of the region 104. The mask layer 910 may be a single-layer structure or a multi-layer structure. In the embodiment, the mask layer 910 is a three-layer structure, which includes a first sub-layer 911, a second sub-layer 912 and a third sub-layer from bottom to top. For example, the first sub-layer 911 may include silicon oxynitride (SiON), the second sub-layer 912 may include titanium nitride (TiN), and the third sub-layer 913 may include a capping layer of silicon containing compound such as silicon dioxide, but not limited thereto. The number and the materials of the layers of the mask layer 910 may be adjusted according to actual needs.

Next, as shown in FIG. 8, a contact material is deposited in the contact vias 930 and 940 and the trench 730, and a portion of the contact material located outside the contact vias 930 and 940 and the trench 730 and the mask layer 910 on the top surface 701 of the dielectric layer 700 are removed with a planarization process, such as a chemical mechanical polishing (CMP) process, so as to form the contact structures 950 and 960 and the metal layer 920, in which the mask layer 910 and the metal layer 920 in the trench 730 together form a composite filling layer 970. The composite filling layer 970 is disposed in the trench 730.

In the embodiment, the metal layer 920 and the contact structures 950 and 960 are formed by the same step. Therefore, the metal layer 920 and the contact structures 950 and 960 are made of the same material. Each of the metal layer 920 and the contact structures 950 and 960 is exemplary a single-layer structure. For example, the contact material may include a metal material, such as aluminum, titanium, tantalum, tungsten, niobium, molybdenum, copper or a combination thereof, so that the metal layer 920 and the contact structures 950 and 960 are single-layer structures made of metal materials. In other embodiments, the metal layer 920 and the contact structures 950 and 960 may be multi-layer structures. In this case, the contact material may further include other materials, such as a barrier material. The barrier material, for example, may include titanium, tantalum, titanium nitride, tantalum nitride, nitrogen or a combination thereof. When depositing the contact material, the barrier material and the metal material may be deposited sequentially, so that the metal layer 920 and the contact structures 950 and 960 may be double-layer structures. The types of the contact materials may be adjusted according to actual needs, so that the number and the materials of the metal layer 920 and the contact structures 950 and 960 may be adjusted accordingly. Thereby, the fabrication of the semiconductor device 1 may be completed.

The aforementioned film layers, such as the inter-metal dielectric layers 310 and 410, the contact etch stop layer 330, etc., may be formed by any suitable methods. For example, the methods may be, but are not limited to, molecular-beam epitaxy (MBE), physical vapor deposition (PVD), chemical vapor deposition (CVD), such as metal organic chemical vapor deposition (MOCVD), sub-atmospheric chemical vapor deposition (SACVD) and plasma-enhanced chemical vapor deposition (PECVD), hydride vapor phase epitaxy (HVPE) and atomic layer deposition (ALD).

Please refer to FIG. 8 and FIG. 9. FIG. 8 is a schematic cross-sectional view showing the semiconductor device 1 according to an embodiment of the present disclosure. FIG. 9 is a schematic top view of the semiconductor device 1 in FIG. 8. For the sake of conciseness, some components are omitted in FIG. 9. For example, at least the mask layer 910 in the trench 730 is omitted. The semiconductor device 1 includes the substrate 100, the plurality of memory cells 500a, 500b, 500c and 500d, the dielectric layer 700 and the trench 730. The substrate 100 defines the memory region 102 having the boundary BR. The memory cells 500a, 500b, 500c and 500d are disposed in the memory region 102. The dielectric layer 700 is disposed on the plurality of memory cells 500a, 500b, 500c and 500d, in which the top surface 701 of the dielectric layer 700 is higher than the top surface 501 of each of the memory cells 500a, 500b, 500c and 500d.

As shown in FIG. 8, the trench 730 includes an asymmetrical profile. Specifically, in the cross-sectional view of the semiconductor device 1, the trench 730 includes the V-shape or the triangle. The trench 730 includes the first sidewall 731 and the second sidewall 732 disposed oppositely. The first sidewall 731 is closer to the one (i.e., the memory cell 500d) of the plurality of memory cells 500a, 500b, 500c and 500d closest to the boundary BR than the second sidewall 732. The first sidewall 731 and the second sidewall 732 may be asymmetrical to each other. The first sidewall 731 may include a concave curve (herein, concave upwardly), and the second sidewall 732 may include a convex curve (herein, convex upwardly). The inclined degree of the first sidewall 731 may be smaller than the inclined degree of the second sidewall 732. As shown in FIG. 9, in the top view of the semiconductor device 1, the trench 730 has an annular shape and surrounds the memory cells 500a, 500b, 500c and 500d.

The semiconductor device 1 may further include the contact vias 930 and 940, the contact structures 950 and 960, and the metal layer 920. The contact vias 930 and 940 are formed in the dielectric layer 700. The contact via 930 exposes the memory cells 500b and 500c. The contact structure 950 is disposed in the contact via 930 and is electrically connected with the memory cells 500b and 500c. The contact via 940 exposes the wire 320, and the contact structure 960 is disposed in the contact via 940 and is electrically connected with the wire 320. The metal layer 920 is disposed in the trench 730, and the top surface 921 of the metal layer 920 is aligned with the top surface 951 of the contact structure 950 and the top surface 961 of the contact structure 960. In the cross-sectional view of the semiconductor device 1, the metal layer 920 includes a V-shape or a triangle. For other details about the semiconductor device 1, reference can be made to the above description and are not repeated herein.

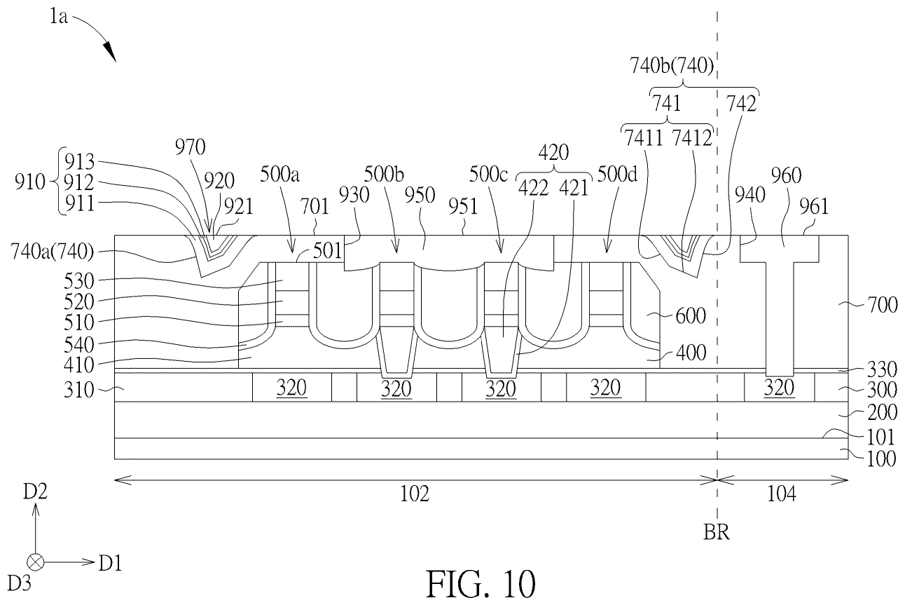

Please refer to FIG. 10, which is a schematic cross-sectional view showing a semiconductor device la according to another embodiment of the present disclosure. The main difference between the semiconductor device la and the semiconductor device 1 is that the shape of the trench 740 is different from the shape of the trench 730. Specifically, in the cross-sectional view of the semiconductor device la, the trench 740 includes a left portion 740a and a right portion 740b, (each of the left portion 740a and the right portion 740b of) the trench 740 includes a quadrangle. The trench 740 includes the first sidewall 741 and the second sidewall 742 disposed oppositely. The aforementioned quadrangle may refer to the shape together formed by the first sidewall 741, the second sidewall 742 and the opening at the top of the trench 740. The first sidewall 741 includes a first wall portion 7411 and a second wall portion 7412. An inclined degree of the first wall portion 7411 is different from an inclined degree of the second wall portion 7412. In some embodiments, the inclined degree of the first wall portion 7411 may be larger than the inclined degree of the second wall portion 7412. For example, when performing the etching process P1 shown in FIG. 5, the distance between the vertical side surface 802 of the patterned mask 800 and the inclined side surface 702 of the protruding portion 710, the protruding height H1 of the protruding portion 710, the height HH of each of the memory cells 500a, 500b, 500c and 500d in the vertical direction D2 may be adjusted, so as to change the shape of the trench 740. The shape of the metal layer 920 may correspond to the shape of the trench 740 to be a quadrangle. For other details about the semiconductor device 1a, reference may be made to the above description and are not repeated herein.

In the present disclosure, in part of the manufacturing process of the semiconductor device, the memory cells protrude from the surface of the semiconductor device (such as the semiconductor device shown in FIG. 3), so that the dielectric layer covering the memory cells has a protruding portion (such as the protruding portion 710 shown in FIG. 4). Therefore, the dielectric layer is required to be planarized to facilitate the formation of other layers on the dielectric layer in subsequent processes. However, it is difficult to planarize the dielectric layer by the known planarization process. Taking the etching process directly performed on the dielectric layer without forming a patterned mask as an example, since the protruding portion and the non-protruding portion are made of the same material, the protruding portion and the non-protruding portion do not have etching selectivity. During the etching process, the heights of the protruding portion and the non-protruding portion are reduced by the same rate and the original surface morphology is remained. Taking the CMP process directly performed on the dielectric layer as another example, the protruding portion is a bulk structure and has a larger polishing area. In practical, it is not easy to remove the protruding portion by the CMP process. Taking forming a patterned mask to expose a portion of the protruding portion, directly etching the portion of the protruding portion to form a sidewall structure (not shown), and then performing a CMP process to remove the sidewall structure as another example, although the polishing area of the sidewall structure is smaller than that of the protruding portion and is favorably to be planarized by the CMP process. However, the sidewall structure is often broken by the polishing external force before the sidewall structure being polished to become flat, and a portion of the dielectric layer connected with the sidewall structure is often broken along with the sidewall structure, which tends to generate dents and/or scratches on the top surface of the dielectric layer. The locations, shapes and depths of the dents and/or scratches cannot be expected and controlled, so as to affect the yield of the subsequent processes. For example, when fabricating a contact structure (such as the contact structures 950 and 960 shown in FIG. 8), the contact materials filled in the dents and/or scratches may generate bridges between different contact structures and cause short circuits. Accordingly, the properties and/or yield of the semiconductor devices formed later are affected.

In the present disclosure, the method for planarizing the dielectric layer disposed on the memory cells is improved. For example, the opening of the patterned mask is configured to expose the protruding portion and the non-protruding portion at the same time, and the etching process is performed to remove the protruding portion and a portion of the non-protruding portion exposed from the opening to form a trench between the memory cell closest to the boundary and the boundary. On one hand, the dielectric layer can be planarized through a single etching process, and the CMP process for planarizing the dielectric layer can be omitted. On the other hand, the position, shape and depth of the trench are controllable, which can prevent the trench from communicating different contact vias (such as the two adjacent ones of the plurality of contact vias 930 shown in FIG. 9). Accordingly, the bridges between different contact structures (such as the two adjacent ones of the plurality of contact structures 950 shown in FIG. 9) caused by the contact material filled in the trench can be prevented. Accordingly, the properties and/or yield of the semiconductor device can be enhanced significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate defining a memory region, wherein the memory region has a boundary;
a plurality of memory cells disposed in the memory region;
a dielectric layer disposed on the plurality of memory cells, wherein a top surface of the dielectric layer is higher than a top surface of each of the plurality of memory cells; and
a trench disposed in the dielectric layer, wherein the trench is located between one of the plurality of memory cells closest to the boundary and the boundary, and the trench comprises an asymmetrical profile.

2. The semiconductor device of claim 1, wherein in a cross-sectional view of the semiconductor device, the trench comprises a V-shape, a triangle or a quadrangle.

3. The semiconductor device of claim 1, wherein in a cross-sectional view of the semiconductor device, the trench comprises a first sidewall and a second sidewall disposed oppositely, and the first sidewall and the second sidewall are asymmetrical to each other.

4. The semiconductor device of claim 3, wherein in the cross-sectional view of the semiconductor device, the first sidewall is closer to the one of the plurality of memory cells closest to the boundary than the second sidewall, the first sidewall comprises a concave curve, and the second sidewall comprises a convex curve.

5. The semiconductor device of claim 3, wherein in the cross-sectional view of the semiconductor device, the first sidewall is closer to the one of the plurality of memory cells closest to the boundary than the second sidewall, and an inclined degree of the first sidewall is smaller than an inclined degree of the second sidewall.

6. The semiconductor device of claim 1, wherein in a top view of the semiconductor device, the trench has an annular shape and surrounds the plurality of memory cells.

7. The semiconductor device of claim 1, wherein one of the plurality of memory cells has a height HH in a vertical direction, a distance SD is between a side of the trench adjacent to the boundary and the one of the plurality of memory cells closest to the boundary in a horizontal direction, and the following condition is satisfied: 0<SD≤2HH.

8. The semiconductor device of claim 1, wherein one of the plurality of memory cells has a height HH in a vertical direction, a distance SD is between a side of the trench adjacent to the boundary and the one of the plurality of memory cells closest to the boundary in a horizontal direction, and the following conditions are satisfied: 1600 Å≤HH≤1750 Å; and 120 nm≤SD≤350 nm.

9. The semiconductor device of claim 1, further comprising:
a contact via formed in the dielectric layer, wherein the contact via exposes at least one of the plurality of memory cells; and
a contact structure disposed in the contact via and electrically connected with the at least one of the plurality of memory cells.

10. The semiconductor device of claim 9, further comprising:
a metal layer disposed in the trench, wherein a top surface of the metal layer is aligned with a top surface of the contact structure.

11. The semiconductor device of claim 1, wherein the one of the plurality of memory cells closest to the boundary is a dummy memory cell.

12. A method for fabricating a semiconductor device, comprising:
providing a substrate, wherein the substrate defines a memory region having a boundary;
forming a plurality of memory cells in the memory region;
forming a dielectric layer to cover the plurality of memory cells, wherein the dielectric layer comprises a protruding portion located on the plurality of memory cells and a non-protruding portion adjacent to the protruding portion; and
removing the protruding portion and a portion of the non-protruding portion to form a trench in the dielectric layer, wherein the trench is located between one of the plurality of memory cells closest to the boundary and the boundary, and the trench comprises an asymmetrical profile.

13. The method of claim 12, wherein in a cross-sectional view of the semiconductor device, the trench comprises a V-shape, a triangle or a quadrangle.

14. The method of claim 12, wherein in a cross-sectional view of the semiconductor device, the trench comprises a first sidewall and a second sidewall disposed oppositely, and the first sidewall and the second sidewall are asymmetrical to each other.

15. The method of claim 14, wherein in the cross-sectional view of the semiconductor device, the first sidewall is closer to the one of the plurality of memory cells closest to the boundary than the second sidewall, the first sidewall comprises a concave curve, and the second sidewall comprises a convex curve.

16. The method of claim 14, wherein in the cross-sectional view of the semiconductor device, the first sidewall is closer to the one of the plurality of memory cells closest to the boundary than the second sidewall, and an inclined degree of the first sidewall is smaller than an inclined degree of the second sidewall.

17. The method of claim 12, wherein in a top view of the semiconductor device, the trench has an annular shape and surrounds the plurality of memory cells.

18. The method of claim 12, wherein removing the protruding portion and the portion of the non-protruding portion to form the trench in the dielectric layer comprises:
forming a patterned mask on the dielectric layer, wherein the patterned mask has an opening, and the opening exposes the protruding portion and the portion of the non-protruding portion; and
etching the protruding portion and the portion of the non-protruding portion.

19. The method of claim 12, further comprising:
forming a contact via in the dielectric layer, wherein the contact via exposes at least one of the plurality of memory cells; and
depositing a contact material in the contact via and the trench.

20. The method of claim 19, further comprising:
removing a portion of the contact material located outside the contact via and the trench.
